(19) United States
(12) Patent Application Publication
(10) Pub. No.: US 2014/0184239 A1
(43) Pub. Date: Jul. 3, 2014

(54) SEMICONDUCTOR DEVICE WITH FUSE SENSING CIRCUIT

(71) Applicant: SK HYNIX INC., Gyeonggi-do (KR)

(72) Inventor: Chul KIM, Gyeonggi-do (KR)

(73) Assignee: SK HYNIX INC., Gyeonggi-do (KR)

(21) Appl. No.: 13/798,628

(22) Filed: Mar. 13, 2013

(30) Foreign Application Priority Data
Dec. 27, 2012 (KR) 10-2012-0155592

(51) Int. Cl. G01R 31/07

(52) U.S. Cl. CPC G01R 31/07
USPC 324/550

(57) ABSTRACT

A semiconductor device may include a fuse unit configured to include a fuse and generate an output voltage according to whether the fuse is ruptured, and a fuse sensing circuit configured to sense whether the fuse is ruptured in response to a reference voltage and the output voltages The reference voltage has a voltage level adapted to leakage current of the fuse unit.

### CROSS-REFERENCE TO RELATED APPLICATIONS

The present application claims priority of Korean Patent Application No. 10-2012-0155592, filed on Dec. 27, 2012, which is incorporated herein by reference in its entirety.

### BACKGROUND

1. Field

Exemplary embodiments of the present invention relate to a fuse sensing circuit and a semiconductor device having the same, and more particularly, to a technology of generating reference voltage for sensing of a fuse rupture.

2.Description of the Related Art

As the number of memory cells and signal lines integrated in a single semiconductor memory device increases with the development of a high integration technology, for the purpose of integrating the memory cells and the signal lines in a limited space of the semiconductor memory device, a line width of an internal circuit is becoming narrower, and a size of the memory cell are becoming smaller. For the above reason, it is highly likely to increase and cause defects in the memory cell of the semiconductor memory device. However, despite the high defect likelihood of the memory cell, a memory may be marketed with a high yield because of a redundancy circuit for relieving defective memory cells in the semiconductor memory device. The redundancy circuit functions through a fuse cut for programming repair addresses corresponding to redundancy memory cells replacing defective memory cells.

In order to program a plurality of fuses included in the redundancy circuit, there are provided with several technologies such as an electrical cutting, a laser cutting, and the like. With the electrical cutting, a fuse is applied with overcurrent and melt and cut. With the laser cutting, a fuse is blown by a laser beam and cut.

Meanwhile, a fuse apparatus is used for various operations in the redundancy circuit and the semiconductor device. For example, the fuse apparatus is used for voltage tuning in a constant voltage generation circuit sensitive to a process, and is used in a control circuit for a test, a control circuit for selecting various modes, and the like.

The fuse apparatus with the electrical cutting mainly uses capacitor transistor and breaks down a gate insulating film of the capacitor transistor by applying a high-voltage stress. When the gate insulating film having infinite impedance is in an activation state where the film is broken due to the stress, that is, is ruptured and the impedance of the capacitor transistor becomes very low, and the information of logic ‘1’ or ‘0’ may be recognized through the impedance change.

FIG. 1 is a circuit diagram illustrating a fuse apparatus according to a prior art.

Referring to FIG. 1, the fuse apparatus of the prior art is configured to include a fuse 10, a stress voltage driving unit 20, and an output unit 30.

When a rupture enable signal Rup is applied, the stress voltage driving unit 20 applies stress voltage HVDD for rupturing the fuse, gate oxide of a capacitor C_{RUP} or the fuse 10 is broken due to electrical stress, and the fuse 10 functions like a resistor.

The output unit 30 senses the state of the fuse 10 based on precharge voltage, e.g. power voltage VDD, which is supplied to the fuse 10 and controlled by a precharge PCG signal, to determine whether the fuse 10 is ruptured. If the fuse 10 is ruptured due to the applied stress, the resistance of the fuse 10 is low, which makes an output voltage V_{OUT} lower than the precharge voltage VDD when the precharge voltage VDD is supplied. If the fuse 10 is not ruptured despite of the applied stress, the resistance of the fuse 10 is kept high, which makes the output voltage V_{OUT} same as the precharge voltage VDD when the precharge voltage VDD is supplied.

According to the prior art, external reference voltage V_{REF}_{_{—}}_{EXT} used together with the output voltage V_{OUT} for sensing the rupture of the fuse 10 is determined by and applied from the outside, Meanwhile, the output voltage V_{OUT}, which should keep expected value for effective sensing of whether or not the fuse 10 is ruptured, cannot keep the expected value due to a gate leakage of a fuse transistor or a loss caused by various reasons after the precharge voltage VDD is supplied, without adjustment of the external reference voltage V_{REF}_{_{—}}_{EXT}. However, according to the prior art, it is difficult to accurately set the external reference voltage V_{REF}_{_{—}}_{EXT} based on the estimation of the variation of the output voltage V_{OUT}. The fuse apparatus according to the prior art may erroneously operate the semiconductor conductor chip due to the sensing error, which may have a negative effect on the memory system.

### SUMMARY

Embodiments of the present invention are directed to a semiconductor device for preventing a sensing error in detecting whether a fuse is ruptured.

In accordance with an embodiment of the present invention, a semiconductor device includes a fuse unit configured to include a fuse and generate an output voltage according to whether the fuse is ruptured, and a fuse sensing circuit configured to sense whether the fuse is ruptured in response to a reference voltage and the output voltage. The reference voltage has a voltage level adapted to leakage current of the fuse unit.

In accordance with another embodiment of the present invention, a fuse sensing apparatus, including a sensing unit configured to sense an input voltage corresponding to whether a fuse is ruptured by comparing the input voltage with a reference voltage, and a reference voltage generation unit configured to generate the reference voltage having a voltage level adapted to leakage current of the fuse.

In accordance with still another embodiment of the present invention, a semiconductor device, including a fuse unit configured to include a fuse having a connection state varying due to a stress and generate an output voltage according to whether the fuse is ruptured, a reference voltage generation unit configured of a replica of the fuse to generate a reference voltage, and a sensing unit configured to sense the output voltage using the reference voltage as a reference.

In accordance with still another embodiment of the present invention, a semiconductor device, comprising a fuse unit configured to include a fuse, selectively rupture the fuse, and generate an output voltage indicating a rupture status of the fuse, a reference voltage generation unit configured to include a replica of the fuse and to generate a reference voltage indicating a rupture status of the replica of the fuse, and sensing unit configured to compare the output voltage and the reference voltage to generate an result signal indicating whether or not the fuse is ruptured.

### BRIEF DESCRIPTION OF THE DRAWINGS

FIG. 1 is a circuit diagram illustrating a fuse apparatus according to a prior art.

FIG. 2 is a block diagram of a semiconductor device in accordance with an embodiment of the present invention,

FIG. 3 is a circuit diagram of the semiconductor device of FIG. 2.

FIG. 4 is a circuit diagram illustrating an embodiment of a sensing unit shown in FIGS. 2 and 3.

FIG. 5 is a circuit diagram illustrating another embodiment of the sensing unit of FIGS. 2 and 3.

FIG. 6 is a timing diagram of the sensing unit shown in FIG. 4.

FIG. 7 is a timing diagram of the sensing unit of FIG. 5.

FIG. 8 is a block diagram illustrating an information processing system to which a memory device in accordance with an embodiment of the present invention is applied.

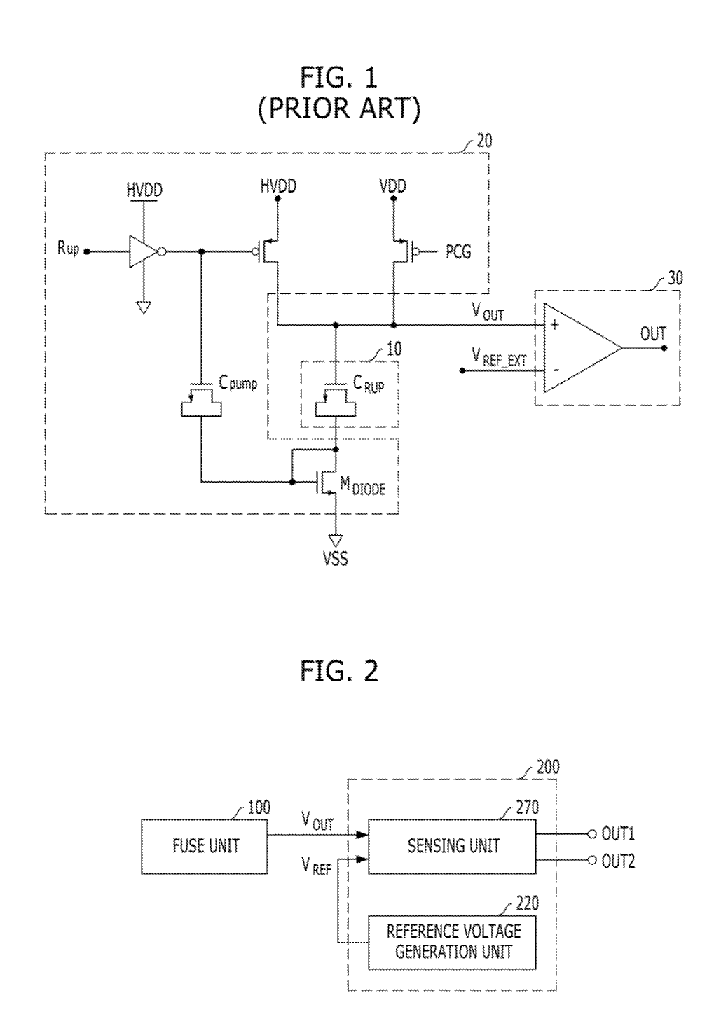

### DETAILED DESCRIPTION

Hereinafter, optimal embodiments of the present invention will be described in detail with reference to the accompanying drawings so that those skilled in the art may easily practice the technical ideas of the present invention. The type of a transistor described below, namely NMOS or PMOS may vary according to a circuit design, and will be modified by those skilled in the art with ease, Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

FIG. 2 is a block diagram of a semiconductor device in accordance with an embodiment of the present invention. Referring to FIG. 2, a semiconductor device is configured to include a fuse unit 100 and a fuse sensing circuit 200. The fuse sensing circuit 200 is configured to include a reference voltage generation unit 220 and a sensing unit 270. The fuse unit 100 generates an output voltage V_{OUT} according to rupture of a fuse included in the fuse unit 100. The reference voltage generation unit 220 generates a reference voltage V_{REF} having a voltage level adapted to variation of the output voltage V_{OUT} of the fuse unit 100. The sensing unit 270 senses the output voltage V_{OUT} of the fuse unit 100 by comparing the output voltage V_{OUT} with the reference voltage V_{REF} to generate sensing result signal OUT1 and OUT2. According to the embodiment of the present invention, the reference voltage generation unit 220 generates the reference voltage V_{REF} as a reference, which is substantially same as the output voltage V_{OUT} of the fuse, which is ruptured or not, with the substantially same variation of the fuse unit 100 due to the gate leakage of a fuse transistor or a loss caused by various reasons when the precharge voltage VDD is supplied so that the fuse sensing unit 270 may correctly sense whether or not the fuse in the fuse unit 100 is ruptured as intended.

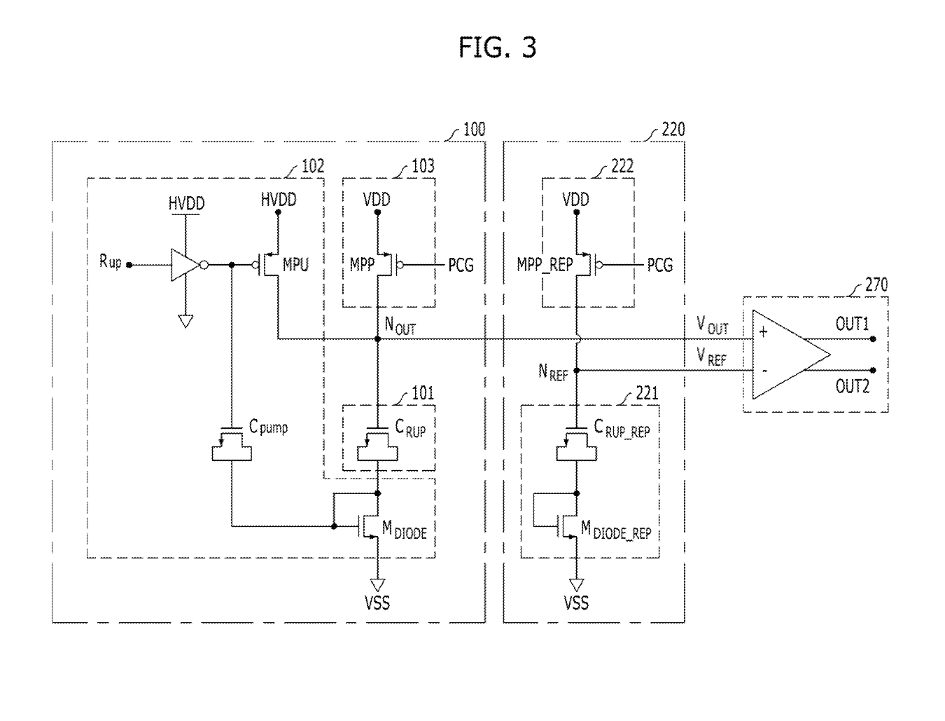

FIG. 3 is a circuit diagram of the semiconductor device of FIG. 2. Referring to FIG, 3, the fuse unit 100 includes the fuse 101 and a fuse driving unit 102 for activating or rupturing the fuse 101. Further, the fuse unit 100 includes a precharge unit 103 controlled by a precharge signal PCG to supply a precharge voltage, e.g. power voltage VDD to an output node N_{OUT}. The reference voltage generation unit 220 includes a replica fuse 221 and a replica precharge unit 222 respectively functioning like the fuse 101 and the precharge unit 103 in the fuse unit 100. The sensing unit 270 senses and compares output voltage V_{OUT} with the reference voltage V_{REF} generated from the reference voltage generation unit 220 as a reference.

The fuse 101 of the fuse unit 100 includes a dielectric substance. The fuse 101 is ruptured by a breakdown of a dielectric substance. The fuse driving unit 102 controls the rupture of the fuse 101. The fuse rupture enable signal Rᵤₚ is input to a gate of a pull-up transistor MPU and the drain of the pull-up transistor MPU is connected with the output node N_{OUT} of the fuse 101. A capacitor C_{PUMP} is connected to the gate of the pull-up transistor MPU and controlled by the fuse rupture enable signal Rᵤₚ. The capacitor C_{PUMP} is also connected with a source and a gate of a diode M_{DIODE} at the other node of the fuse 101. When the fuse rupture enable signal Rᵤₚ is applied, the output node N_{OUT} of the fuse 101 is supplied with first stress voltage HVDD. The first stress voltage HVDD preferably has a higher voltage level than the power voltage VDD. Further, the diode M_{DIODE} is connected between the fuse 101 and the ground voltage VSS. The diode M_{DIODE} boosts the ground voltage VSS according to the fuse rupture enable signal Rᵤₚ to generate second stress voltage LVSS. That is, the other node of the fuse 101 is boosted to a negative voltage level. In the embodiment, the diode M_{DIODE} is configured of an NMOS transistor, but may be configured of a PMOS transistor. Further, in the embodiment, the first stress voltage HVDD is defined as positive voltage higher than the power voltage VDD and the second stress voltage LVSS is defined as negative voltage lower than the ground voltage VSS. For reference, the embodiment is described as an example in which the negative voltage generated by boosting the ground voltage VSS that is supplied to the fuse 101, but in accordance with the embodiment, an example in which the negative voltage generated by boosting the ground voltage VSS is supplied to the output node N_{OUT} of the fuse 101, and the positive voltage generated by boosting the power voltage VDD is supplied to the other node of the fuse 101 may be practiced.

The fuse driving unit 102 may supply the first stress voltage HVDD to the output node N_{OUT} and the second stress voltage LVSS to the other node of the fuse 101 at substantially the same time according to the control of the fuse rupture enable signal Rᵤₚ. Therefore, the voltage difference between the output node N_{OUT} and the other node of the fuse 101, which is the electrical stress applied to the fuse 101, is increased in a moment. The connection state of the fuse 101 is changed due to the electrical stress applied across the fuse 101. For example, the resistance of the fuse 101 is changed from high to low due to the electrical stress applied.

After the application of the electrical stress to the fuse 101, the precharge unit 103 supplies the precharge voltage VDD to the fuse 101 in response to the precharge signal PCG for sensing of the rupture status of the fuse 101. When the precharge signal PCG is applied to the gate of a precharge transistor MPP of the precharge unit 103, the precharge unit 103 supplies the precharge voltage VDD to the fuse 101 at the output node N_{OUT} where the output voltage V_{OUT} varies according to whether the fuse is ruptured. If the fuse 101 is not ruptured despite of the application of the electrical stress to the fuse 101, the output voltage V_{OUT} has a value around the precharge voltage VDD. If the fuse 101 is ruptured due to the application of the electrical stress to the fuse 101, the output voltage V_{OUT} has a value lower than the precharge voltage VDD.

The reference voltage generation unit 220 includes the replica fuse 221 and the replica precharge unit 222 functioning like the fuse 101 and the precharge unit 103, respectively, in the fuse unit 100, According to the embodiment of the present invention, the reference voltage generation unit 220 generates the reference voltage V_{REF} as a reference, which is substantially sane as the output voltage V_{OUT} of the fuse 101 whether it is ruptured or not, with the substantially same variation of the fuse unit 100 due to the gate leakage of a fuse transistor or a loss caused by various reasons when the precharge voltage VDD is supplied so that the fuse sensing unit 270 may correctly sense whether or not the fuse 101 is ruptured as intended The replica fuse 221 is configured to include a diode M_{DIODE}_{_{—}}_{REP} that is connected between the ground power voltage VSS and a replica fuse C_{RUP}_{_{—}}_{REP} functioning similarly to the fuse 101 of the fuse unit 100. The replica fuse C_{RUP}_{_{—}}_{REP} may be ruptured or not, which may be varied according to a design. When the replica fuse C_{RUP}_{_{—}}_{REP} ruptured is used, the reference voltage generation unit 220 generates the reference voltage V_{REF} as a reference, which is substantially the same as the output voltage V_{OUT} of the fuse 101 when it is ruptured. When the replica fuse C_{RUP}_{_{—}}_{REP} not ruptured is used, the reference voltage generation unit 220 generates the reference voltage V_{REF} as a reference, which is substantially the same as the output voltage V_{OUT} of the fuse 101 when it is not ruptured. The replica precharge unit 222 is configured to include a replica precharge transistor MPP_REP providing the precharge voltage VDD in response to the precharge signal PCG. When the precharge signal PCG is applied to the gate of the replica precharge transistor MPP_REP of the replica precharge unit 222, the replica precharge unit 222 supplies the precharge voltage VDD to the replica fuse C_{RUP}_{_{—}}_{REP} at a reference node N_{REF} where the reference voltage V_{REF} varies according to use of the replica fuse C_{RUP}_{_{—}}_{REP} whether it is ruptured or not. When the replica fuse C_{RUP}_{_{—}}_{REP} not ruptured is used, the reference voltage V_{REF} has a value around the precharge voltage VDD. When the replica fuse C_{RUP}_{_{—}}_{REP} ruptured is used, the reference voltage V_{REF} has a value lower than the precharge voltage VDD. The design of the replica precharge transistor MPP_REP may vary according to the characteristic of the precharge signal PCG, which will be described hereinafter.

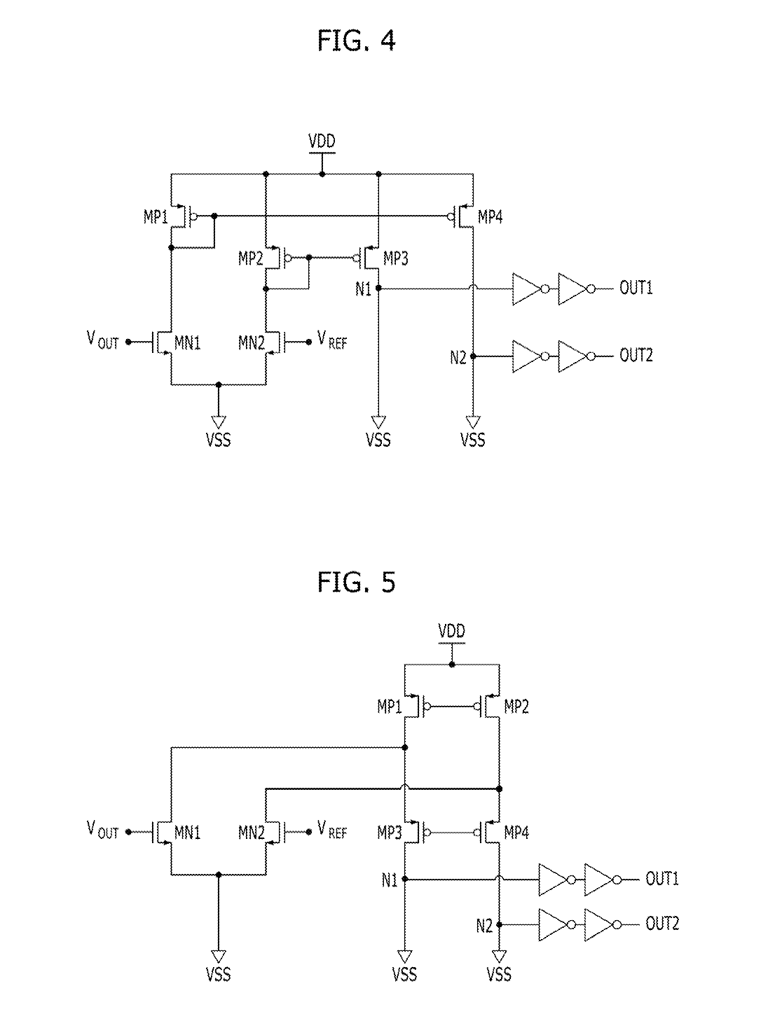

FIG. 4 is a circuit diagram illustrating an embodiment of a sensing unit of FIGS. 2 and 3. Referring to FIG. 4, the sensing unit 270 is configured of a first NMOS transistor MN1 and a second NMOS transistor MN2 controlled by an output voltage V_{OUT} and a reference voltage V_{REF} and drains of each transistor are connected with a ground power voltage VSS. A source terminal of the first NMOS transistor MN1 is connected with a gate and a drain of a first PMOS transistor MP1 and a gate of a fourth PMOS transistor MP4. A source terminal of the second NMOS transistor MN1 is connected with a gate and a drain of a second PMOS transistor MP2 and a gate of a third PMOS transistor MP3. Source terminals of the first, second, third, and fourth PMOS transistors MP1 MP2, MP3, and MP4 are each connected with an external power voltage VDD, A first output terminal OUT1 is connected with a drain of the third PMOS transistor MP3 and a ground power voltage VSS at a first output node N1. A second output terminal OUT2 is connected with a drain of the fourth PMOS transistor MP4 and the ground power voltage VSS at a second output node N2. Voltage values of a first output node Ni and a second output node N2 are amplified at the first output terminal OUT1 and the second output terminal OUT2 through two inverter chains to be output as a logic level (‘high or low’). The first, second, third, and fourth PMOS transistors MP1, MP2, MP3, and MP4 are of the substantially the same size and each source terminal thereof is connected with the external power voltage VDD to apply the same size of current to the first, second, third, and fourth PMOS transistors MP1, MP2, MP3, and MP4. If the output voltage V_{OUT} is higher than the reference voltage V_{REF}, which may be a case of the fuse 101 not ruptured despite of the application of the electrical stress, the current running through the first NMOS transistor MN1 is larger than that of the second NMOS transistor MN2, Therefore, a larger amount of charges are accumulated at the second output node N2 than at the first output node N1, such that a voltage level of the second output terminal OUT2 is higher than a voltage level of the first output terminal OUT1. The first output terminal OUT1 is output as ‘low’ and the second output terminal OUT2 is output as ‘high’. If the output voltage V_{OUT} is lower than the reference voltage V_{REF}, which may be a case of the ruptured fuse 101 as intended, the current running through the second NMOS transistor MN2 is larger than that of the first NMOS transistor MN1. A larger amount of charges are accumulated at the first output node N1 than at the second output node N2, such that the voltage level of the first output terminal OUT1 is higher than the voltage level of the second output terminal OUT2. Therefore, the first output terminal OUT1, is output as ‘high’ and the second output terminal OUT2 is output as ‘low’. The value of the output voltage V_{OUT} may be similar to that of the reference voltage V_{REF}. In this case, the logic levels of the first output terminal OUT1 and the second output terminal OUT2 are of substantially same value, which informs that the output voltage V_{OUT} falls within a predetermined threshold range of the reference voltage V_{REF}. In this case, it is determined that the fuse 101 is not ruptured despite of the application of the electrical stress.

FIG. 5 is a circuit diagram illustrating another embodiment of the sensing unit of FIGS. 2 and 3.

The sensing unit shown in FIG. 5 may be of use when the reference voltage V_{REF} is a high voltage. Referring to FIG. 5, the drains of the first NMOS transistor MN1 and the second NMOS transistor MN2 controlled by the output voltage V_{OUT} and the reference voltage V_{REF} are connected with the ground power voltage VSS. The source terminal of the first NMOS transistor MN1, the drain terminal of the first PMOS transistor MP1 and the source terminal of the third PMOS transistor MP3 are connected with one another. The source terminal of the second NMOS transistor MN2, the drain terminal of the second PMOS transistor MP2 and the source terminal of the fourth PMOS transistor MP4 are connected with one another. The gates of the first PMOS transistor MP1 and the second PMOS transistor MP2 are connected with each other. The gates of the third PMOS transistor MP3 and the fourth transistor MP4 are also connected with each other. A first output terminal OUT1 is connected with the drain of the third PMOS transistor MP3 and the ground power voltage VSS at a first output node N1. A second output terminal OUT2 is connected with the drain of the fourth PMOS transistor MP4 and the ground power voltage VSS at a second output node N2. Voltage values of a first output node Ni and a second output node N2 are amplified at the first output terminal OUT1 and the second output terminal OUT2 through two inverter chains to be output as a logic level (‘high or low’). That is, as described above, in the case in which there is a difference between the output voltage V_{OUT} and the reference voltage V_{REF}, the first output terminal OUT1 and the second output terminal OUT2 are output as different logic levels (‘high’ or ‘low’). On the other hand, in the case in which the output voltage V_{OUT} is similar to the reference voltage V_{REF}, the logic levels of the first output terminal OUT1 and the second output terminal OUT2 are of substantially the same value, which informs that the output voltage V_{OUT} falls within the predetermined threshold range of the reference voltage V_{REF}. In this case, it is determined that the fuse 101 is not ruptured despite of the application of the electrical stress.

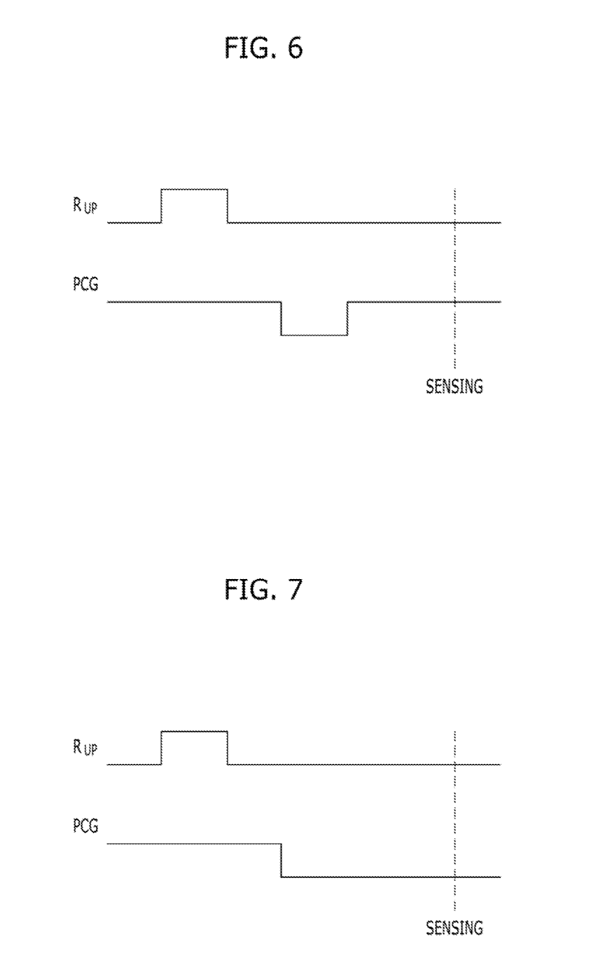

Next, the precharge signal PCG will be described with reference to FIGS. 6 and 7 in order to help understanding of the characteristics of the precharge signal PCG.

FIG. 6 is a timing diagram of the sensing unit of FIG. 4. The precharge signal PCG is enabled after application of the fuse rupture enable signal Rᵤₚ, and then is disabled before the sensing unit 270 is driven. This kind of the precharge signal PCG is used in the general fuse sensing apparatus. The replica precharge transistor MPP_REP of the replica precharge unit 222 may have a driving force that is a sum of the capacitance values of (including ‘parasitic capacitance’) the pull-up transistor MPU and the precharge transistor MPP to have the same environment as the fuse unit 100.

FIG. 7 is a timing diagram of the sensing unit of FIG. 5. The precharge signal PCG is enabled after application of the fuse rupture enable signal Rᵤₚ, and then stays disabled while the sensing unit 270 is driven. In this case, the capacitance values (including ‘parasitic capacitance’) of the pull-up transistor MPU and the precharge transistor MPP may be neglected. Therefore, the replica precharge transistor MPP_REP may be of the same size as the precharge transistor MPP. With the replica precharge transistor MPP REP of the same size as the precharge transistor MPP, when the fuse 101 is ruptured, the impedance of the fuse 101 becomes small. Since the precharge signal PCG is continuously enabled, even though the precharge transistor MPP and the replica precharge transistor MPP_REP are turned on, the output voltage V_{OUT} may drop to low voltage as the impedance of the fuse 10 becomes small. However, when the replica fuse 221 is not ruptured and thus still has high impedance, the reference voltage V_{REF} is increased. That is, the reference voltage V_{REF} has a high voltage value in the vicinity of the external power VDD. In this case, the sensing unit 270 shown in FIG. 5 is used when the reference voltage V_{REF} is high voltage.

According to the embodiments of the present invention, the reference voltage V_{REF} is generated under the condition that the reference voltage generation unit 220 is designed to provide substantially the same environment as the fuse unit 100, thereby reducing the errors on detecting whether the fuse 100 is ruptured. That is, it may be accurately discriminated whether the fuse 101 is ruptured by comparing the output voltage V_{OUT} with the reference voltage V_{REF}. In addition, the semiconductor device may discriminate the value informing that the output voltage V_{OUT} falls within a predetermined threshold voltage of the reference voltage V_{REF}. In this case, it is determined that the fuse 101 is not ruptured despite of the application of the electrical stress.

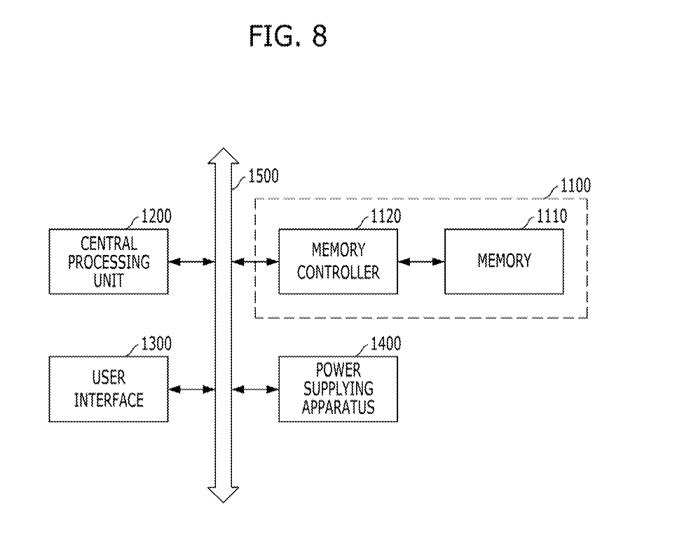

The fuse sensing apparatus proposed by various embodiments may be applied to various memory apparatuses such as a DRAM and a flash memory. FIG. 8 is a block diagram illustrating an information processing system to which a memory device in accordance with an embodiment of the present invention is applied.

Referring to FIG. 8, an information processing system may include a memory system 1100, a central processing unit 1200, a user interface 1300, and a power supplying apparatus 1400 and may perform data communication with each other through a bus 1500

The memory system 1100 may include a memory device 1110 and a memory controller 1120 and the memory device 1110 may be stored with data processed by the central processing unit 1200 or data input through the user interface from the outside. Importantly, the memory device 1100 includes the fuse sensing apparatus proposed by various embodiments.

The information processing system may configure all the electronic devices for data storage and may be applied to various in mobile devices such as a memory card, a semiconductor disk (solid state disk (SSD)), and a smart phone.

As set forth above, the memory device can accurately sense whether the fuse in which the desired information is programmed is ruptured and may increase the reliability of the memory device using the results.

In accordance with the embodiments of the present invention, the fuse sensing apparatus may adjust the reference voltage to the variation of the output voltage of the fuse thereby correctly sensing whether or not the fuse is ruptured regardless of the variation of the output voltage of the fuse, and thus improving the reliability of the semiconductor device and reducing the yield loss.

While the present invention has been described with respect to the specific embodiments, it will be apparent to those skilled in the art that various changes and modifications may be made without departing from the spirit and scope of the invention as defined in the following claims, Also, it is to be understood that various changes and modifications within the technical scope of the present invention are made by a person having ordinary skill in the art to which this invention pertains

What is claimed is:

1. A semiconductor device, comprising:
a fuse unit configured to include a fuse and generate an output voltage according to whether the fuse is ruptured; and
a fuse sensing circuit configured to sense whether the fuse is ruptured in response to a reference voltage and the output voltage,
wherein the reference voltage has a voltage level adapted to leakage current of the fuse unit.

2. The semiconductor device of claim 1, wherein the fuse sensing circuit further includes a reference voltage generation unit configured to generate the reference voltage and include a replica of the fuse.

3. The semiconductor device of claim 1, wherein the fuse includes a dielectric substance and is ruptured by a breakdown of the dielectric substance.

4. A fuse sensing apparatus, comprising:
a sensing unit configured to sense an input voltage corresponding to whether a fuse is ruptured by comparing the input voltage with a reference voltage; and
a reference voltage generation unit configured to generate the reference voltage having a voltage level adapted to leakage current of the fuse.

5. The fuse sensing apparatus of claim 4, wherein the reference voltage generation unit includes a replica of the fuse.

6. The fuse sensing apparatus of claim 4, wherein the sensing unit comprises a comparator outputting a value when the input voltage falls within a predetermined threshold range of the reference voltage.

7. A semiconductor device, comprising:
a fuse unit configured to include a fuse having a connection state varying due to a stress and generate an output voltage according to whether the fuse is ruptured;
a reference voltage generation unit configured of a replica of the fuse to generate a reference voltage; and
a sensing unit configured to sense the output voltage using the reference voltage as a reference.

8. The semiconductor device of claim 7, wherein the fuse unit includes:
the fuse;
a fuse driving unit configured to activate a rupture of le fuse; and
a precharge unit configured to supply a precharge voltage to an output node connected to the fuse in response to a precharge signal,
wherein a voltage level of the output node varies according to the rupture of the fuse and is supplied to the sensing unit as the output voltage.

9. The semiconductor device of claim S, wherein the reference voltage generation unit includes:
the replica of the fuse; and
a replica precharge unit configured to include a replica of the precharge unit supplying the precharge voltage to a reference node connected to the replica of the fuse in response to the precharge signal,
wherein a voltage level of the reference node varies according to the rupture of the replica of the fuse and is supplied to the sensing unit as the reference voltage.

10. The semiconductor device of claim 9, wherein
the fuse driving unit includes a pull up unit configured to be connected to the output node, and
the replica precharge unit has a driving force that is a sum of capacitance values of the precharge unit and the pull up unit.

11. The semiconductor device of claim 10, wherein the precharge signal is enabled after application of the stress to the fuse and is disabled before the sensing unit is driven,

12 The semiconductor device of claim 10, wherein the precharge signal is enabled after application of the stress to the fuse and stays enabled while the sensing unit is driven.

13. The semiconductor device of claim 7, wherein the sensing unit includes a comparator that compares the output voltage with the reference voltage and outputs a value when the output voltage falls within a predetermined threshold range of the reference voltage.

14. A semiconductor device, comprising:
a fuse unit configured to include a fuse, selectively rupture the fuse, and generate an output voltage indicating a rupture status of the fuse;
a reference voltage generation unit configured to include a replica of the fuse and to generate a reference voltage indicating a rupture status of the replica of the fuse; and
sensing unit configured to compare the output voltage and the reference voltage to generate an result signal indicating whether or not the fuse is ruptured.

15. The semiconductor device of claim 14, wherein the fuse unit further includes:
a fuse driving unit configured to rupture the fuse; and
a precharge unit configured to supply a precharge voltage to an output node connected to the fuse in response to a precharge signal,
wherein a voltage level of the output node varies according to the rupture of the fuse and is supplied to the sensing unit as the output voltage.

16. The semiconductor device of claim 5 wherein the reference voltage generation unit further includes a replica precharge unit supplying the precharge voltage to a reference node connected to the replica of the fuse in response to the precharge signal,
wherein a voltage level of the reference node varies according to the rupture of the replica of the fuse and is supplied to the sensing unit as the reference voltage.

17. The semiconductor device of claim 14, wherein the reference voltage generation unit further includes a precharge unit supplying a precharge voltage to a reference node connected to the replica of the fuse in response to a precharge signal,
wherein a voltage level of the reference node varies according to the rupture of the replica of the fuse and is supplied to the sensing unit as the reference voltage.

18. The semiconductor device of claim 14, wherein the sensing unit generate the result signal when the output voltage falls within a predetermined threshold range of the reference voltage.
